(19) United States
(12) Patent Application Publication
(10) Pub. No.: US 2008/0048756 A1
(43) Pub. Date: Feb. 28, 2008

(54) Semiconductor Integrated Circuit Externally Outputting Oscillation Signal and Electronic Device Including the Same

(75) Inventors: Satoshi Mikami, Kyoto (JP); Morihiko Tokumoto, Kyoto (JP); Masayu Fujiwara, Kyoto (JP)

Correspondence Address: FISH & RICHARDSON P.C., P.O. BOX 1022, MINNEAPOLIS, MN, 55440-1022, US

(73) Assignee: ROHM CO., LTD., Kyoto (JP)

(21) Appl. No.: 11/775,360

(22) Filed: Jul. 10, 2007

(30) Foreign Application Priority Data
Jul. 11, 2006 (JP) 2006-190456
May 24, 2007 (JP) 2007-138220

(51) Int. Cl. H03K 17/28; H03K 17/00

(52) U.S. Cl. 327/398; 327/365

(57) ABSTRACT

A semiconductor integrated circuit includes an oscillation circuit outputting an oscillation signal, and a switch circuit switching whether the oscillation signal received from the oscillation circuit is to be output to the outside or not.

### BACKGROUND OF THE INVENTION

1. Field of the Invention

The present invention relates to a semiconductor integrated circuit and an electronic device including the circuit. More specifically, the present invention relates to a semiconductor integrated circuit externally outputting an oscillation signal and an electronic device including such a circuit.

2. Description of the Background Art

In an electronic device such as a DVD recorder, a clock is generated internally, and using the generated clock, signal processing and the like are performed. Therefore, a general electronic device includes a semiconductor integrated circuit generating the clock using, for example, an oscillator (crystal) (see, for example, Japanese Patent Laying-Open No. 10-107620 (Patent Document 1)).

In a conventional semiconductor integrated circuit generating a clock, by way of example, an oscillator is externally connected, an oscillation circuit generating an oscillation signal by forming a loop with the oscillator is included, and the oscillation signal output by the oscillation circuit is amplified by a buffer or the like and output as the clock. Further, to an output of the semiconductor integrated circuit generating the clock, a semiconductor integrated circuit performing signal processing and the like using the clock is connected. Assuming that the semiconductor integrated circuit using the clock has high driving capability, the clock output from the semiconductor integrated circuit is transmitted as a noise, through a ground layer of a substrate to the loop formed by the oscillator and the oscillation circuit. Then, a problem arises that, in particular, in the situation immediately after the power on in which the oscillation signal has small amplitude, the oscillation signal is offset by the transmitted noise and generation of the oscillation signal fails.

An object of the present invention is to provide a semiconductor integrated circuit capable of generating the oscillation signal in a stable manner and to provide an electronic device including such a circuit.

According to an aspect, the present invention provides a semiconductor integrated circuit, including an oscillation circuit outputting an oscillation signal, and a switch circuit switching whether the oscillation signal received from the oscillation circuit is to be output to the outside or not.

Preferably, the semiconductor integrated circuit further includes a control circuit controlling the switch circuit such that the oscillation signal received from the oscillation circuit is output to the outside after a prescribed time period from when a power is supplied to the oscillation circuit.

Preferably, the semiconductor integrated circuit further includes a low pass filter delaying a voltage same as the voltage supplied as the power to the oscillation circuit and outputting the delayed voltage to the switch circuit, and receiving the delayed voltage, the switch circuit outputs the oscillation signal received from the oscillation circuit to the outside.

Preferably, the semiconductor integrated circuit further includes a counter counting a rising edge or a falling edge of the oscillation signal and outputting a control signal when the counted value reaches a prescribed value or higher, and receiving the control signal, the switch circuit outputs the oscillation signal received from the oscillation circuit to the outside.

According to another aspect, the present invention provides an electronic device, including a semiconductor integrated circuit, wherein the semiconductor integrated circuit includes an oscillation circuit outputting an oscillation signal, and a switch circuit switching whether the oscillation signal received from the oscillation circuit is to be output to the outside or not.

By the present invention, the oscillation signal can be generated in a stable manner.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a configuration of an electronic device in accordance with a first embodiment of the present invention.

FIGS. 2A to 2D are waveform diagrams representing an operation of the semiconductor integrated circuit in accordance with the first embodiment of the present invention externally outputting a clock.

FIG. 3 is a waveform diagram representing phase relations among an oscillation signal XIN, an oscillation signal XOUT and a clock CLK.

FIG. 4 shows a configuration of a modification of the electronic device in accordance with the first embodiment of the present invention.

FIG. 5 shows a configuration of a modification of the electronic device in accordance with the first embodiment of the present invention.

FIG. 6 shows a configuration of an electronic device in accordance with a second embodiment of the present invention.

FIG. 7 shows a configuration of an electronic device in accordance with a third embodiment of the present invention.

### DESCRIPTION OF THE PREFERRED EMBODIMENTS

In the following, embodiments of the present invention will be described with reference to the figures. In the figures, the same or corresponding portions are denoted by the same reference characters and description thereof will not be repeated.

### First Embodiment

[Configuration and Basic Operation]

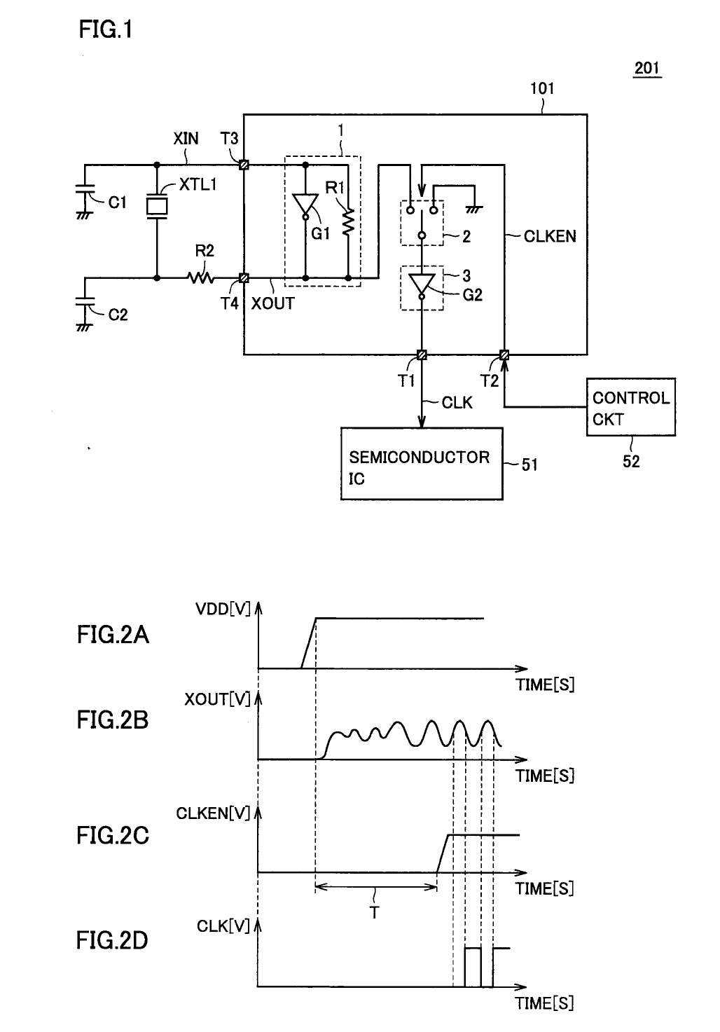

FIG. 1 shows a configuration of an electronic device in accordance with a first embodiment of the present invention. Referring to FIG. 1, an electronic device 201 includes a semiconductor integrated circuit 101, a control circuit 52, a semiconductor integrated circuit 51, capacitors C1 and C2, an oscillator XTL1 and a resistor R2. Semiconductor integrated circuit 101 includes an oscillation circuit 1, a switch circuit 2, an output buffer 3 and terminals T1 to T4. Oscillation circuit 1 includes an inverted gate G1 and a resistor R1. Output buffer 3 includes an inverted gate G2.

Oscillation circuit 1 receives through terminal T3 an oscillation signal XIN that has passed through oscillator XTL1, and outputs an oscillation signal XOUT to switch circuit 2. More specifically, inverted gate G1 in oscillation circuit 1 inverts and amplifies the oscillation signal XIN, outputs the amplified signal as oscillation signal XOUT to switch circuit 2, and further outputs the signals through terminal T4 and resistor R2 to oscillator XTL1. Resistor R1 adjusts potentials at the input and output of inverted gate G1 to be close to a threshold voltage for the inverted gate G1 to determine H or L level of an input signal. Because of such a configuration, even if inverted gate should receive a signal of very small amplitude, output of a signal fixed at the H level or L level from the output of inverted gate G1 could be prevented. Thus, the oscillation circuit can reliably start oscillation. Resistor R2 is provided for adjusting output of inverted gate GI.

Oscillator XTL1 oscillates at a prescribe frequency, for example, at 27 MHz. Specifically, oscillator XTL1 attenuates frequency components other than the prescribed frequency, for example, 27 MHz, of the oscillation signal XOUT received from oscillation circuit 1.

Switch circuit 2 switches whether the oscillation signal received from oscillation circuit 1 is to be output to output buffer 3 or not, based on a control signal CLKEN received from terminal T2. Specifically, when the control signal CLKEN is at the L level, switch circuit 2 connects the input of output buffer 3 to a fixed potential, for example, the ground potential, and when the control signal CLKEN is at the H level, it connects the input of output buffer 3 to the output of oscillation circuit 1.

Output buffer 3 converts the oscillation signal received from switch circuit 2 to a rectangular wave and outputs it from terminal T1 to the outside of semiconductor integrated circuit 101. It is noted that output buffer 3 may have a configuration simply for amplifying and outputting the oscillation signal, rather than converting the oscillation signal received from switch circuit 2 to a rectangular wave.

Semiconductor integrated circuit 51 performs a signal processing or the like using the clock CLK received from semiconductor integrated circuit 101. By way of example, semiconductor integrated circuit 51 is an MPEG2 decoder, performing decoding process in compliance with MPEG (Moving Picture Coding Experts Group) 2 standard, using the clock CLK received from semiconductor integrated circuit 101. Alternatively, semiconductor integrated circuit 51 is a DA (Digital to Analog) converter, converting a digital signal to an analog signal using the clock CLK received from semiconductor integrated circuit 101.

Next, an operation when the semiconductor integrated circuit in accordance with the first embodiment of the present invention outputs the clock to the outside will be described.

[Operation]

FIGS. 2A to 2D are waveform diagrams representing the operation when the semiconductor integrated circuit in accordance with the first embodiment of the present invention outputs the clock to the outside.

First, when power is supplied to semiconductor integrated circuit 101, that is, when a power supply voltage VDD is supplied to semiconductor integrated circuit 101 (FIG. 2A), inverted gate G1 amplifies the noise generated between inverted gate G1 and oscillator XTL1 and outputs a signal such as shown in FIG. 2B, as oscillation signal XOUT.

After a prescribed time period T from the supply of power supply voltage VDD to semiconductor integrated circuit 101, control circuit 52 outputs an H level control signal CLKEN representing “enable” to terminal T2 of semiconductor integrated circuit 101. Specifically, until the prescribed time period T passes after the supply of power supply voltage VDD to semiconductor integrated circuit 101, control circuit 52 continuously outputs an L level control signal CLKEN representing “disable” to terminal T2 of semiconductor integrated circuit 101 (FIG. 2C).

Receiving the H level control signal CLKEN from control circuit 52 through terminal T2, switch circuit 2 outputs the oscillation signal received from oscillation circuit 1 to output buffer 3.

Output buffer 3 converts the oscillation signal received from switch circuit 2 to a rectangular wave, and outputs it as the clock CLK through terminal T1 to the outside of semiconductor integrated circuit 101 (FIG. 2D).

In the conventional semiconductor integrated circuit generating a clock, when the semiconductor integrated circuit using the clock has high driving capability, the clock output from the semiconductor integrated circuit is transmitted as a noise, through a ground layer of a substrate to the loop formed by the oscillator and the oscillation circuit. Then, a problem arises that, in particular, in the situation immediately after the power on in which the oscillation signal has small amplitude, the oscillation signal is offset by the transmitted noise and generation of the oscillation signal fails.

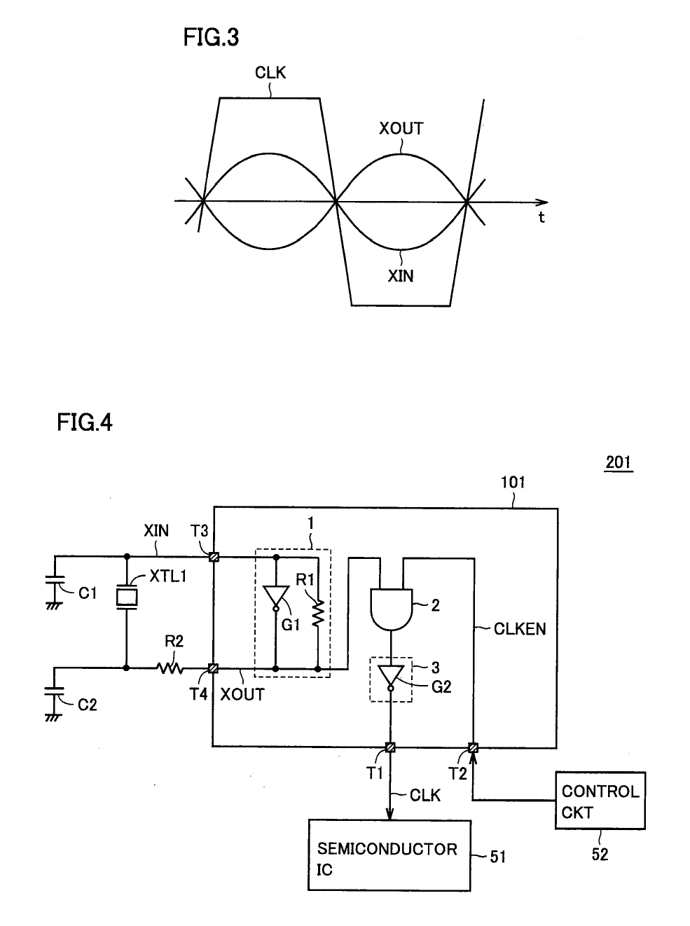

Here, FIG. 3 is a waveform diagram representing phase relations among oscillation signal XIN, oscillation signal XOUT and the clock CLK.

Referring to FIG. 3, because of inverted gate G2, oscillation signal XIN and the clock CLK have almost matching phases, and because of inverted gate G1, oscillation signals XIN and XOUT have almost inverse phases. Therefore, oscillation signal XOUT and the clock CLK have almost inverse phases.

Assuming that the semiconductor integrated circuit 51 has high driving capability, the clock CLK is transmitted as a noise, through a ground layer of a substrate of electronic device 201 to the loop formed by the oscillator XTL and the oscillation circuit 1. Then, particularly in a prescribed time period T of FIG. 2, that is, in the situation immediately after the power is turned on in which the oscillation signal has small amplitude, oscillation signal XOUT having the phase approximately inverse to the phase of clock CLK would be offset by the transmitted noise, and oscillation circuit 1 would fail to generate the oscillation signal.

In the semiconductor integrated circuit in accordance with the first embodiment of the present invention, however, oscillation circuit 1 receives the oscillation signal XIN that has passed through oscillator XTL1 through terminal T3 and outputs the oscillation signal XOUT as the oscillation signal, to switch circuit 2. Switch circuit 2 switches whether the oscillation signal received from oscillation circuit 1 is to be output to the outside of semiconductor integrated circuit 101 or not through output buffer 3, based on the control signal CLKEN received through terminal T2.

By such a configuration, it becomes possible not to output the clock signal CLK to the outside of semiconductor integrated circuit 101 in the situation immediately after power on in which the oscillation signal has small amplitude, and therefore, offset of the oscillation signal XOUT by the noise caused by the clock CLK, that is, failure of oscillation signal generation by oscillation circuit 1, can be prevented. Therefore, in the semiconductor integrated circuit in accordance with the first embodiment of the present invention, the oscillation signal can be generated in a stable manner.

[Modification 1]

FIG. 4 shows a configuration of a modification of the electronic device in accordance with the first embodiment of the present invention. Referring to FIG. 4, switch circuit 2 is an AND gate, and when the control signal CLKEN is at the L level, it outputs an L level signal to output buffer 3 and when the control signal CLKEN is at the H level, it outputs the oscillation signal from oscillation circuit 1 to output buffer 3.

Except for this point, the configuration and operation are the same as those of electronic device 201, and therefore, detailed description thereof will not be repeated here.

[Modification 2]

FIG. 5 shows a configuration of a modification of the electronic device in accordance with the first embodiment of the present invention. Referring to FIG. 5, electronic device 202 includes a semiconductor integrated circuit 102, semiconductor integrated circuit 51, capacitors C1 and C2, oscillator XTL1, and resistor R2. Semiconductor integrated circuit 102 includes oscillation circuit 1, switch circuit 2, output buffer 3, terminals T1, T3 and T4, and control circuit 52.

Except for this point, the configuration and operation are the same as those of electronic device 201, and therefore, detailed description thereof will not be repeated here.

Next, another embodiment of the present invention will be described with reference to the figures. In the figures, the same or corresponding portions are denoted by the same reference characters and description thereof will not be repeated.

### Second Embodiment

The present embodiment is directed to an electronic device in which the configuration of controlling switch circuit 2 is modified from the electronic device in accordance with the first embodiment. Except for the contents described in the following, the electronic device is the same as that of the first embodiment.

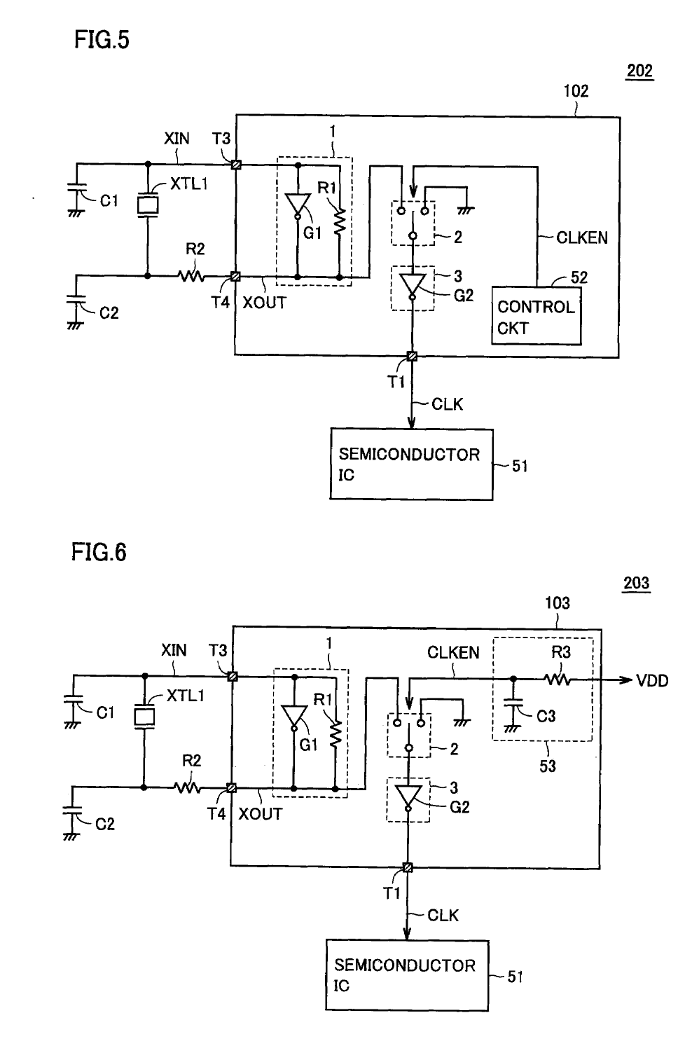

FIG. 6 shows a configuration of the electronic device in accordance with the second embodiment of the present invention.

Referring to FIG. 6, an electronic device 203 includes a semiconductor integrated circuit 103, semiconductor integrated circuit 51, capacitors C1 and C2, oscillator XTL1, and resistor R2. Semiconductor integrated circuit 103 includes oscillation circuit 1, switch circuit 2, output buffer 3, terminals T1, T3 and T4, and a low pass filter 53. Low pass filter 53 includes a resistor R3 and a capacitor C3.

Low pass filter 53 delays power supply voltage VDD, which is the same as the voltage supplied as the power to oscillation circuit 1, and outputs the delayed voltage to switch circuit 2.

Receiving the voltage delayed at low pass filter 53, switch circuit 2 outputs the oscillation signal received from oscillation circuit 1 to the outside.

Except for this point, the configuration and operation are the same as those of electronic device 201, and therefore, detailed description thereof will not be repeated here.

By such a configuration, it becomes possible not to output the clock signal CLK to the outside of semiconductor integrated circuit 103 in the situation immediately after power on in which the oscillation signal has small amplitude, and therefore, offset of the oscillation signal XOUT by the noise caused by the clock CLK, that is, failure of oscillation signal generation by oscillation circuit 1, can be prevented. Therefore, in the semiconductor integrated circuit in accordance with the second embodiment of the present invention, as in the electronic device in accordance with the first embodiment, the oscillation signal can be generated in a stable manner.

Low pass filter 53 may be arranged outside the semiconductor integrated circuit 103.

Next, another embodiment of the present invention will be described with reference to the figures. In the figures, the same or corresponding portions are denoted by the same reference characters and description thereof will not be repeated.

### Third Embodiment

The present embodiment is directed to an electronic device in which the configuration of controlling switch circuit 2 is modified from the electronic device in accordance with the first embodiment. Except for the contents described in the following, the electronic device is the same as that of the first embodiment.

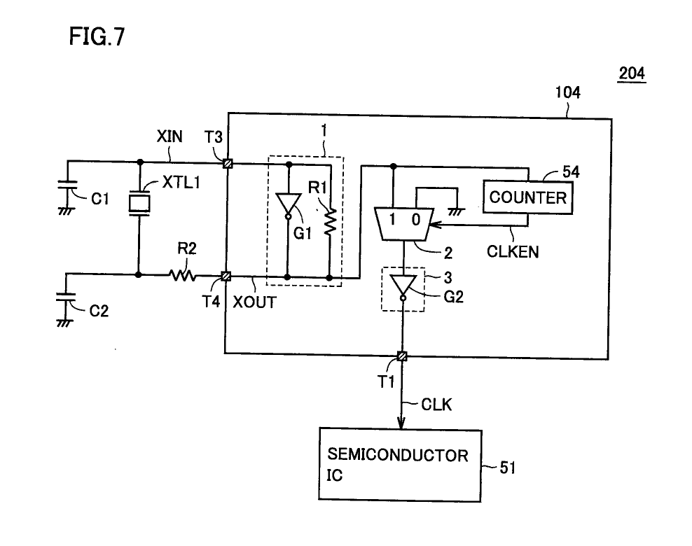

FIG. 7 shows a configuration of an electronic device in accordance with a third embodiment of the present invention.

Referring to FIG. 7, an electronic device 204 includes a semiconductor integrated circuit 104, semiconductor integrated circuit 51, capacitors C1 and C2, oscillator XTL1 and resistor R2. Semiconductor integrated circuit 104 includes oscillation circuit 1, switch circuit 2, output buffer 3, terminals T1, T3 and T4, and a counter 54, Counter 54 counts a rising edge or a falling edge of the oscillation signal received from oscillation circuit 1, and when the count value reaches a prescribed value or higher, outputs an H level control signal CLKEN to switch circuit 2.

Switch circuit 2 is a multiplexer, and when control signal CLKEN is at the L level, it outputs an L level signal to output buffer 3 and when the control signal CLKEN is at the H level, it outputs the oscillation signal from oscillation circuit 1 to output buffer 3.

By such a configuration, it becomes possible not to output the clock signal CLK to the outside of semiconductor integrated circuit 104 in the situation immediately after power on in which the oscillation signal has small amplitude, and therefore, offset of the oscillation signal XOUT by the noise caused by the clock CLK, that is, failure of oscillation signal generation by oscillation circuit 1, can be prevented. Therefore, in the semiconductor integrated circuit in accordance with the third embodiment of the present invention, as in the electronic device in accordance with the first embodiment, the oscillation signal can be generated in a stable manner.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor integrated circuit, comprising
an oscillation circuit outputting an oscillation signal; and
a switch circuit switching whether the oscillation signal received from said oscillation circuit is to be output to the outside or not.

2. The semiconductor integrated circuit according to claim 1, further comprising
a control circuit controlling said switch circuit such that the oscillation signal received from said oscillation circuit is output to the outside after a prescribed time period from when a power is supplied to said oscillation circuit.

3. The semiconductor integrated circuit according to claim 1, further comprising
a low pass filter delaying a voltage same as the voltage supplied as the power to said oscillation circuit and outputting the delayed voltage to said switch circuit; wherein
receiving said delayed voltage, said switch circuit outputs the oscillation signal received from said oscillation circuit to the outside.

4. The semiconductor integrated circuit according to claim 1, further comprising
a counter counting a rising edge or a falling edge of said oscillation signal and outputting a control signal when the count value reaches a prescribed value or higher; wherein
receiving said control signal, said switch circuit outputs the oscillation signal received from said oscillation circuit to the outside.

5. An electronic device, comprising a semiconductor integrated circuit, wherein
said semiconductor integrated circuit includes
an oscillation circuit outputting an oscillation signal; and
a switch circuit switching whether the oscillation signal received from said oscillation circuit is to be output to the outside or not.
